(19) United States
(12) Patent Application Publication
(10) Pub. No.: US 2025/0181090 A1
(43) Pub. Date: Jun. 5, 2025

(54) SUPPLY-DEPENDENT THRESHOLD FOR OVER-CURENT PROTECTION

(71) Applicant: TEXAS INSTRUMENTS INCORPORATED, Dallas, TX (US)

(72) Inventors: Sachin S, Bangalore (IN); Ashish Ohja, Bangalore (IN)

(21) Appl. No.: 18/523,967

(22) Filed: Nov. 30, 2023

(51) Int. Cl. G05F 1/56; H03K 5/24; H03K 17/687

(52) U.S. Cl. CPC G05F 1/56; H03K 5/24; H03K 17/687

(57) ABSTRACT

A reference signal generation circuit includes a voltage-to-current (V2I) converter having a terminal. A first current mirror has a first terminal and a second terminal. The first terminal is coupled to the terminal of the V2I converter. A second current mirror has a first terminal, a second terminal, and a third terminal. The first terminal of the second current mirror is coupled to the second terminal of the first current mirror. A third current mirror has a first terminal coupled to the second terminal of the first current mirror. The third current mirror is coupled to the third terminal of the second current mirror.

### BACKGROUND

Many electrical applications include over-current protection (OCP). In many OCP techniques, a current is compared to a threshold level. If the current exceeds the threshold level, an over-current signal is asserted. Logic may respond to an assertion of the over-current signal by, for example, turning off a switch (e.g. a transistor) to thereby turn off the current.

### SUMMARY

In an example, a reference signal generation circuit includes a voltage-to-current (V2I) converter having a terminal. A first current mirror has a first terminal and a second terminal. The first terminal is coupled to the terminal of the V2I converter. A second current mirror has a first terminal, a second terminal, and a third terminal. The first terminal of the second current mirror is coupled to the second terminal of the first current mirror. A third current mirror has a first terminal coupled to the second terminal of the first current mirror. The third current mirror is coupled to the third terminal of the second current mirror.

### BRIEF DESCRIPTION OF THE DRAWINGS

FIG. 1 is a block diagram of a system which includes over-current protection circuits, in an example.

FIG. 2 is a circuit schematic of an over-current protection circuit including an example of a current sense circuit.

FIG. 3 is a circuit schematic of an over-current protection circuit including another example of a current sense circuit.

FIG. 4 is. a graph illustrating a fixed over-current protection threshold, in an example.

FIG. 5 is a graph illustrating a piece-wise linear over-current protection threshold, in another example.

FIG. 6 is a circuit schematic of an example of a reference signal generation circuit usable in the over-current protection circuits of FIG. 1-3.

FIG. 7 is a circuit schematic of another example of a reference signal generation circuit usable in the over-current protection circuits of FIG. 1-3.

FIG. 8 is a flow diagram of a method for detecting an over-current condition, in an example.

### DETAILED DESCRIPTION

The same reference numbers or other reference designators are used in the drawings to designate the same or similar (either by function and/or structure) features.

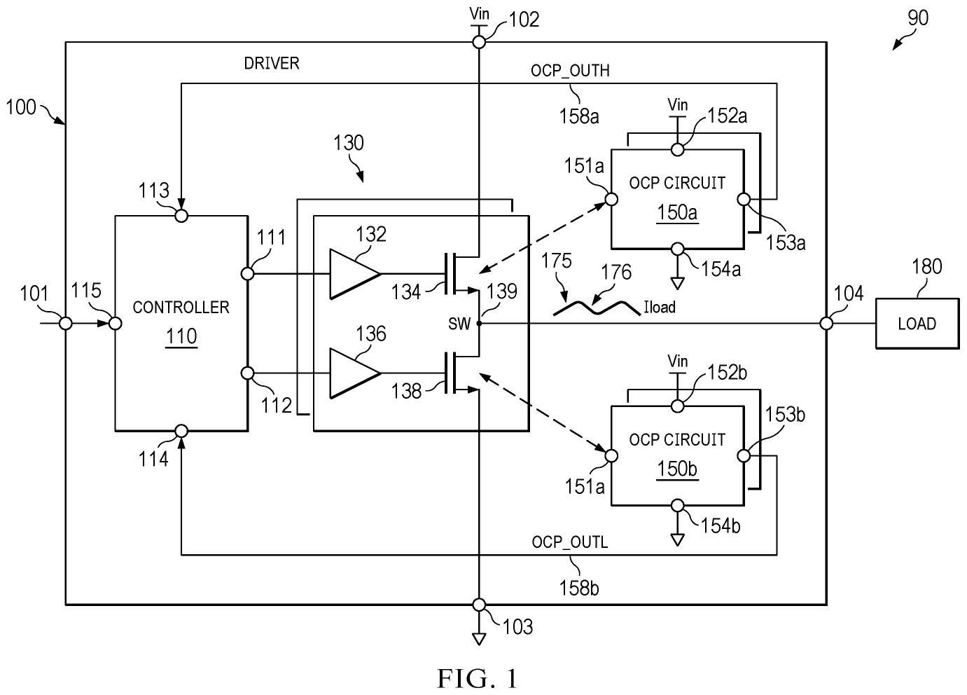

FIG. 1 is a block diagram of a system 90, in an example. System 90 includes a driver 100 and a load 180. Driver 100 includes driver terminals 101, 102, 103, and 104. Terminals 102 and 103 are coupled to a supply voltage Vin and ground, respectively. Terminal 101 is an input terminal for the driver 100, and terminal 104 is an output terminal which is coupled to load 180. In one example, load 180 may be a motor such as a stepper motor, a direct current (DC) motor, a multi-phase (e.g., three-phase) motor, etc. In another example, load 180 may be a power stage of a power converter such as a buck converter, a boost converter, etc. As a power converter, load 180 may include one or more inductors and capacitors.

Driver 100 includes controller 110, one or more half-bridges 130, and a pair of over-current protection (OCP) circuits 150a and 150b coupled to each half-bridge 130. Driver 100 may include additional components as well. Controller 110 includes controller terminals 111, 112, 113, 114, and 115. OCP circuit 150a includes terminals 151a, 152a, 153a, and 154a. OCP circuit 150b includes terminals 151b, 152b, 153b, and 154b. Driver terminal 101 is coupled to controller terminal 115. Each half-bridge 130 includes gate drivers 132 and 136 and transistors 134 and 138. Controller terminal 111 is coupled to an input of gate driver 132, and controller terminal 112 is coupled to an input of gate driver 136. Terminal 151a of OCP circuit 150a is coupled to transistor 134, and terminal 151b of OCP circuit 150b is coupled to transistor 138. The dashed lines coupling terminals 151a and 151b to their respective transistors 134 and 138 represent different ways (described below) that a current sense circuit within the OCP circuits 150a and 150b can be coupled to transistors 134 and 138. Terminals 152a and 154a of OCP circuit 150a are coupled to driver terminals 102 and 103, respectively. Similarly, terminals 152b and 154b of OCP circuit 150b are coupled to driver terminals 102 and 103, respectively. Terminal 153a of OCP circuit 150a is coupled to controller terminal 113, and terminal 153b of OCP circuit 150b is coupled to controller terminal 114.

Within each half-bridge, transistors 134 and 138 may be n-channel field effect transistors (NFETs) as shown in the example of FIG. 1, or either or both of transistors 134 and 138 may be implemented as another type of transistors. In the example of FIG. 1, the drain terminal of transistor 134 is coupled to driver terminal 102, and the source terminal of transistor 138 is coupled to driver terminal 103. The source terminal of transistor 134 is coupled to the drain terminal of transistor 138 at switch terminal 139. Switch terminal 139 is coupled to driver terminal 104. Load 180 is coupled to driver terminal 104. An output of gate driver 132 is coupled to the gate terminal of transistor 134, and an output of gate driver 136 is coupled to the gate terminal of transistor 138.

In one example, driver 100 including controller 110, half-bridge(s) 130, and OCP circuits 150a and 150b may be fabricated on the same semiconductor die (integrated circuit (“IC)). Load 180 may be a separate component from the semiconductor die containing the components of driver 100. In another example, driver 100 and load 180 may be fabricated as separate semiconductor dies but packaged together as a single packaged device.

In response to a signal at driver terminal 101, in one example, controller 110 generates a pulse width modulation (PWM) signal (e.g., internal to controller 110) to control the on and off states of transistors 134 and 138 within a given half-bridge 130. Based on the PWM signal, controller 110 controls the duty cycle of the timing of transistors 134 and 138. Controller 110 generates a control signal at terminal 111 to turn on and off transistor 134. Controller 110 also generates a control signal at terminal 112 to turn on and off transistor 138. Responsive to the control signals from terminals 111 and 112, gate drivers 132 and 136 generate suitable voltages to turn on and off the corresponding transistors 134 and 138.

Responsive to transistor 134 being turned on, current flows from driver terminal 102 through transistor 134 to load 180. Responsive to transistor 138 being turned on, current flows from driver terminal 103 through transistor 138 to load 180. In one example, load 180 is an inductive load (e.g., a motor, an inductor, etc.). When transistor 134 turns on, current Iload through the transistor to the load ramps up as shown by reference numeral 175 due to the inductance of the load. When transistor 138 turns on, current to the load continues to flow but through transistor 138 but ramps down as indicated by reference numeral 176. OCP circuits 150a and 150b are operative to detect short-circuit conditions associated with the transistor 134, 138 to which each OCP circuit is coupled. As described below, each OCP circuit 150a and 150b generates a threshold current based on the magnitude of voltage Vin and compares the current sensed from its corresponding transistor 134, 138 to the threshold current to determine whether an over-current condition has occurred. If OCP circuit 150a does not detect an over-current condition, OCP circuit 150a forces signal OCP_OUTH 158a at its terminal 153a to a first logic state (e.g., logic high). Similarly, if OCP circuit 150b does not detect an over-current condition, OCP circuit 150b forces signal OCP_OUTL 158b at its terminal 153b to the first logic state.

Any of multiple short-circuit conditions can be detected by one or the other of OCP circuits 150a and 150b. For example, if driver terminal 104 is inadvertently shorted to ground, an over-current condition would occur when controller 110 causes transistor 134 to turn on. OCP circuit 150a detects the over-current condition associated with transistor 134 and asserts signal OCP_OUTH 158a to a second logic state (e.g., logic low) at terminal 153a to controller terminal 113. Controller 110 may respond to the asserted signal at terminal 113 by turning off transistor 134. Similarly, if driver terminal 104 is inadvertently shorted to voltage Vin, an over-current condition would occur when controller 110 causes transistor 138 to turn on. OCP circuit 150b detects the over-current condition associated with transistor 138 and asserts signal OCP_OUTL 158b to the second logic state at terminal 153b to controller terminal 114. Controller 110 may respond to the asserted signal at terminal 114 by, for example, turning off transistor 138.

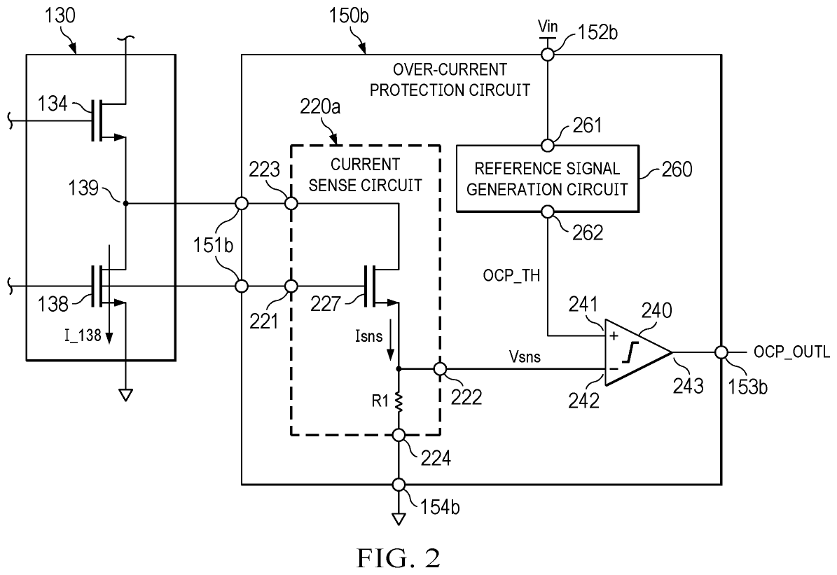

FIG. 2 is a schematic diagram of an example OCP circuit 150b. OCP circuit 150a can be implemented with the same circuit shown in FIG. 2. In this example, OCP circuit 150b includes a current sense circuit 220a, a comparator 240, and a reference signal generation circuit 260. Reference signal generation circuit 260 has terminals 261 and 262. Current sense circuit 220a has terminals 221, 222, 223, and 224. Comparator 240 has terminals 241, 242, and 243. In the example of FIG. 2, terminal 241 is the positive (+) terminal of comparator 240, and terminal 242 is the negative (−) terminal of comparator 240. Terminal 243 is the output of comparator 240.

In the example of FIG. 2, terminal 221 of current sense circuit 220a is coupled to the gate of transistor 138 and terminal 223 is coupled to the drain of transistor 138. Terminals 221 and 223 represent terminal 151b of over-current protection circuit 150b. Terminal 224 of current sense circuit 220a is coupled to terminal 154b of over-current protection circuit 150b. Terminal 222 of current sense circuit 220a is coupled to terminal 242 of comparator 240. Terminal 261 of reference signal generation circuit 260 is coupled to terminal 152b of OCP circuit 150b. Terminal 262 of reference signal generation circuit 260 is coupled to the positive terminal (terminal 241) of comparator 240. The comparator's terminal 243 is coupled to terminal 153b of OCP circuit 150b.

Current sense circuit 220a in the example of FIG. 2 includes transistor 227 and resistor R1. Transistor 227 can be an NFET as shown or a different type of transistor. The gate and drain terminals of transistor 227 are coupled to terminals 221 and 223, respectively, and thus to the gate and drain terminals, respectively, of transistor 138. Resistor R1 is coupled between the source terminal of transistor 227 and terminal 154b of OCP circuit 150b.

The size of a field effect transistor (FET) refers to the ratio of its channel's width (W) to its channel's length (L). In an example, transistor 227 is smaller than transistor 138. The current Isns through transistor 227 is proportional to current I_138 through transistor 138. The ratio of the magnitude of current Isns to current I_138 is the ratio of the effective impedance of transistor 227 plus the resistance of resistor R1 to the impedance of transistor 138. For example, if the size of transistor 227 is one-one hundredth the size of transistor 138, then, for a resistor R1 with a much smaller resistance than the impedance of transistor 227, the magnitude of current Isns will be approximately one-one hundredth the magnitude of current I_138. Current Isns flows through resistor R1 and produces a voltage Vsns across resistor R1 that is Isns*R1. Accordingly, voltage Vsns is proportional to current I_138 and, accordingly, is a proxy for current I_138.

Reference signal generation circuit 260 receives voltage Vin at its terminal 261. As described below, reference signal generation circuit 260 generates a threshold current based on voltage Vin and converts the threshold current to a threshold voltage OCP_TH which may be a proxy for the threshold current. The threshold voltage OCP_TH is provided to the positive terminal (terminal 241) of comparator 240. Comparator 240 compares current I_138 to a threshold current to determine whether an over-current condition is present by comparing the threshold voltage OCP_TH to voltage Vsns. With the threshold voltage OCP_TH provided at the positive terminal of comparator 240 and voltage Vsns provided at the negative terminal (terminal 242) of comparator 240, comparator 240 causes its output signal OCP_OUTL to be logic high if Vsns, and thus current Isns, is smaller than the threshold voltage OCP_TH, and thus the threshold current generated internal to the reference signal generation circuit 260. Otherwise, comparator 240 causes its output signal OCP_OUTL to be logic low if Vsns is larger than the threshold voltage OCP_TH.

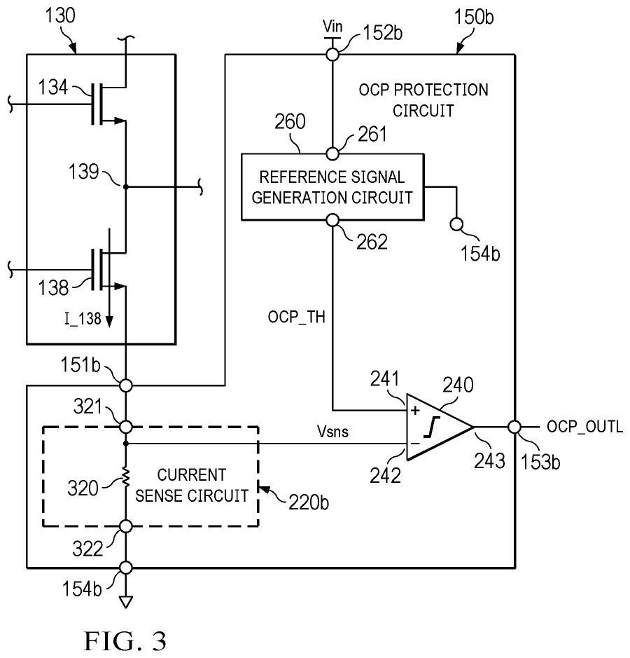

FIG. 3 is a schematic diagram of an example OCP protection circuit 150b having a current sense circuit 220b instead of current sense circuit 220a as in FIG. 2. Current sense circuit 220b includes terminals 321 and 322. Terminals 321 and 322 are coupled to terminals 151b and 154b, respectively, of OCP protection circuit 150b. Current sense circuit 220b includes a resistive device 320 coupled between terminals 321 and 322. In one example, resistive device 320 includes a resistor. In other examples, resistive device 320 is coupled between the drain of transistor 138 and load 180 or between the drain of transistor 134 and driver terminal 102. The resistance of resistive device 320 is relatively low, e.g., 100 milli-ohms. Current I_138 flows through transistor 138 also flows through resistive device 320 thereby resulting in a voltage Vsns across resistive device 320 that is proportional to current I_138. Comparator 240 and reference signal generator 260 in FIG. 3 are largely the same as in FIG. 2.

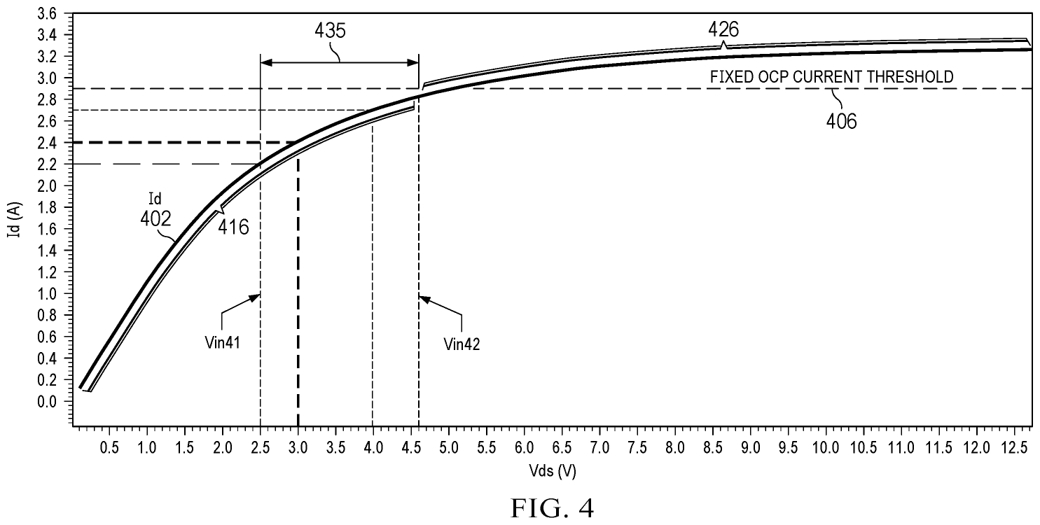

FIG. 4 is a graph in which the y-axis represents transistor drain current (Id) and the x-axis represents the drain-to-source voltage (Vds) for the transistor for a given gate-to-source voltage (Vgs). Plot 402 is an example of the relationship between drain current for transistor 134, 138 and the transistor's Vds. Plot 402 shows the magnitude of the current through transistor 134, 138 for a given value of its Vds. During normal operation (no short circuit condition), the Vds of transistor 134, 138 is less than voltage Vin. For example, Vin may be 4V but the Vds applied to transistor 134, 138 may be 3V. Per plot 402, for a Vds of 3V, the transistor's drain current will be about 2.4 A. However, if the switch terminal 139 is inadvertently shorted to driver terminal 102 (which has voltage Vin) when controller 110 turns on, for example, transistor 138, the Vds for transistor 138 will be equal to 4V instead of 3V, and the drain current through transistor 138 will be equal to 2.7 A instead of 2.4 A. In this example in which Vin equals 4V, the short-circuit will result in a current of 2.7.

In general, the current through a transistor 134, 138 for a short circuit condition (switch terminal shorted to ground or Vin) is a function of Vin. The voltage Vin may be any voltage within a range from Vin41 to a higher operating voltage (e.g., 12.5V). In the example of FIG. 4, Vin41 is 2.5V and Vin42 is 4.5V. Accordingly, the short circuit current through transistor 134, 138 may range from approximately 2.2 A to 3.3 A depending on the magnitude of Vin.

In one example, OCP circuits 150a and 150b may be configured to have a fixed OCP current threshold 406, which is consistent with the largest value for the transistor current during a short circuit condition, Vin equal to 4.5V. In the example of FIG. 4, the fixed OCP current threshold 406 is 2.9 A. OCP circuits 150a and 150b compare the magnitude of the current through their respective transistor 134 or 148 to the fixed OCP current threshold 406, for example, through the corresponding voltage proxies Vsns and OCP_TH. In one example, the fixed OCP current threshold 406 implemented by OCP circuits 150a and 150b is set at a level approximately equal to the sensed current Isns corresponding to the fixed OCP current threshold 406. Responsive to an OCP circuit 150a, 150b detecting that the current of the corresponding transistor 134, 138 has reached or exceeded the fixed OCP current threshold 406, the OCP circuit 150a, 150b asserts the corresponding output signal OCP_OUTH 158a or OCP_OUTL 158b to indicate an over-current condition.

However, if a voltage Vin is provided at a level that is less than the voltage Vin42 (e.g., at 4V instead of at 4.5V), the drain current through the transistor 134, 138 during a short-circuit condition will be 2.7 A which is less than the fixed OCP current threshold 406 of 2.9 A, short circuits for values of Vin greater than 4V will not be detectable (false negative). On the other hand, if the fixed OCP current threshold 406 were set to a lower value, e.g., at 2.7 A, then the OCP circuits 150a, 150b will falsely detect as a short circuit condition (false positive) a drain current that is above the fixed OCP current threshold of 2.7 A simply due to a Vin being used that is large enough that the Vds of the transistor 134, 138 is greater than 4V.

In examples that implement a fixed OCP current threshold, half-bridges 130 may include a temperature sensor to sense the temperature of transistor 134 and a separate temperature sensor to sense the temperature of transistor 138. The output signals from such temperature sensors may be monitored by controller 110. Controller 110 may use the temperature sensor's signals to determine if an over-current condition has occurred for voltages VM that are within the range 435. Controller 110 may use the output signals 158a and 158b from the OCP circuits 150a and 150b, respectively, for a voltage VM that is at or voltage VM42.

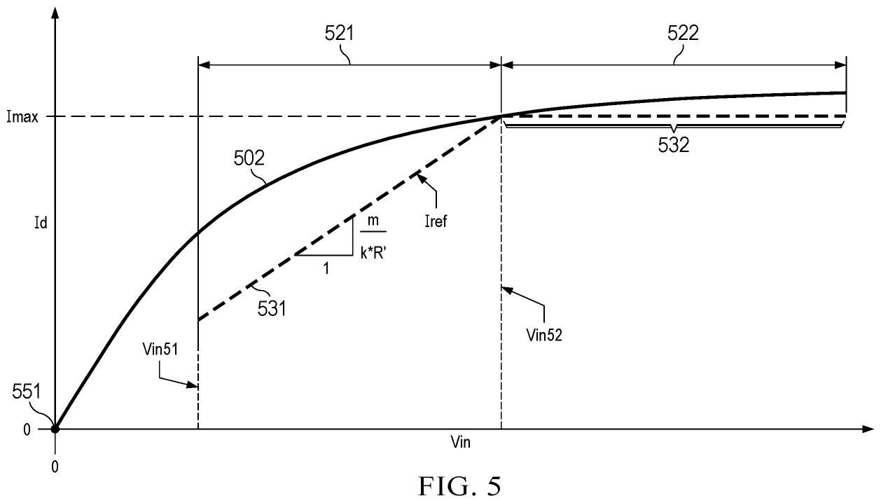

FIG. 5 is a graph in which the y-axis represents current and the x-axis represents the voltage Vin. Plot 502 represents the current through transistor 134, 138 relative to voltage Vin for the short circuit condition in which the switch terminal 139 is shorted to ground or Vin. In either case, the Vds of the transistor is Vin. In contrast to a fixed OCP current threshold 406, the graph of FIG. 5 includes a piece-wise linear reference current Iref relative to voltage Vin. The piece-wise linear plot of current Iref includes a linear segment 531 corresponding to a first range 521 of voltage Vin between Vin51 and Vin52. Linear segment 531 for current Iref is such that current Iref is proportional to voltage Vin. In a second range 522 for voltage Vin above Vin52, current Iref is approximately constant, e.g., not dependent on voltage Vin. In an example, each OCP circuit 150a and 150b generates a reference current Iref according to the piece-wise linear graph of FIG. 5. For linear segment 531, the reference current Iref scales with respect to Vin and, accordingly with respect to Vin, for a short circuit condition. Accordingly, the risk of false positives and false negatives for short circuit detection is reduced compared to the use of a fixed OCP current threshold 406 as in FIG. 4. Accordingly, systems whose OCP circuits implement a piece-wise linear reference current advantageously may not also include the temperature sensors described above.

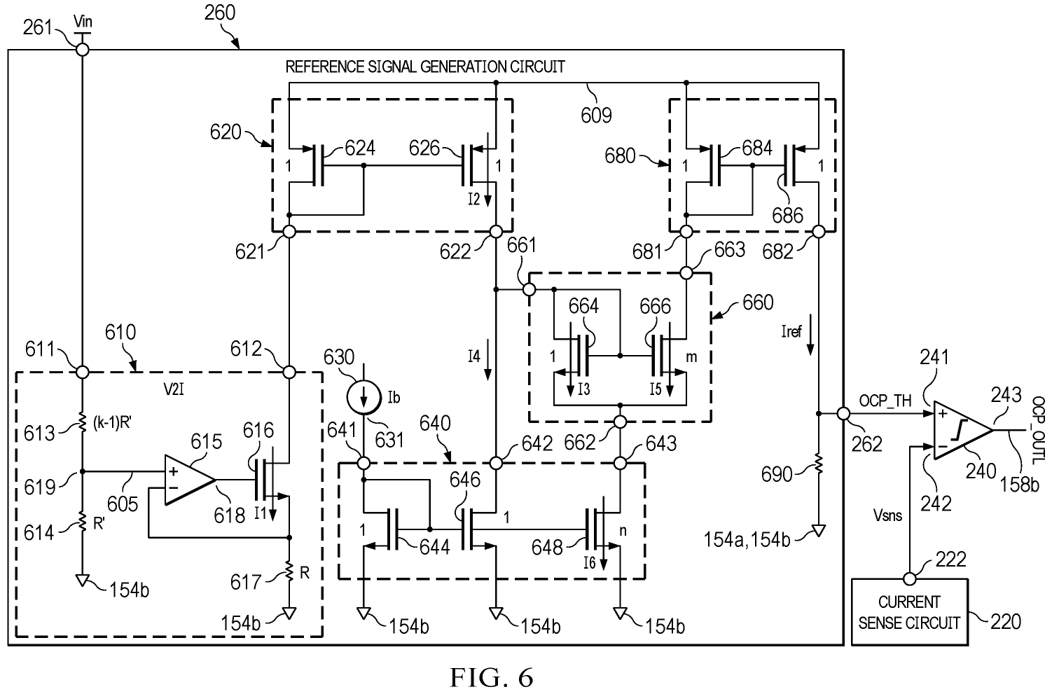

FIG. 6 is a circuit schematic of an example reference signal generation circuit 260 usable for either or both OCP circuits 150a or 150b. In this example, reference signal generation circuit 260 includes a voltage-to-current (V2I) converter 610, current mirrors 620, 640, 660, and 680, current source circuit 630, and resistor 690. V2I converter 610 has terminals 611 and 612. Current mirror 620 has terminals 621 and 622. Current mirror 640 has terminals 641, 642, and 643. Current mirror 660 has terminals 661, 662, and 663. Current mirror 680 has terminals 681 and 682. Current source circuit 630 has a terminal 631.

Terminal 611 of V2I converter 610 is coupled to terminal 261 of reference signal generation circuit 260. Terminal 612 of V2I converter 610 is coupled to terminal 621 of current mirror 620. Terminal 622 of current mirror 620 is coupled to terminal 642 of current mirror 640. Terminal 631 of current source circuit 630 is coupled to terminal 641 of current mirror 640. Terminal 662 of current mirror 660 is coupled to terminal 643 of current mirror 640. Terminal 681 of current mirror 680 is coupled to terminal 661 of current mirror 660. Terminal 682 of current mirror 680 is coupled to resistor 690 and to the positive terminal (terminal 241) of comparator 240. Resistor 690 is coupled between terminal 68 and ground, e.g., terminal 154a or 154b in the respective OCP circuit 150a, 150b.

In the example of FIG. 6, V2I converter 610 includes resistors 613, 614, and 617, an operational-amplifier (OP-AMP) 615, and a transistor 616. Transistor 616 is an NNFET is this example but can be a different type of transistor in other examples. Resistors 613 and 614 are coupled in series between terminals 611 and 154a (154b) and form a voltage divider. In one example, the resistance of resistor 614 is R′ and the resistance of resistor 613 is (k−1)*R′, where R′ is any suitable resistance (e.g., 100 kilo-ohms) and k is an integer greater than 1. The connection 619 between resistors 613 and 614 is coupled to the positive terminal of OP-AMP 615. The output 618 of OP-AMP is coupled to the gate of transistor 616. The source of transistor 616 is coupled to resistor 617 and to the negative input of OP-AMP 615. Resistor 617 is coupled between the source of transistor 617 and ground (e.g., terminal 154a/154b). The drain of transistor 616 is coupled to terminal 612.

Current mirror 620 includes transistors 624 and 626. In this example, transistors 624 and 626 are p-channel field effect transistors (PFETs) but can be implemented as other types of transistors in other examples. The gates of transistors 624 and 626 are coupled together and to the drain of transistor 624 and to terminal 621. The sources of transistors 624 and 626 are coupled together and to supply voltage terminal 609, which may be equal to Vin or an internally-generated voltage, e.g., a voltage smaller than Vin. The drain of transistor 626 is coupled to terminal 622. The drain current through transistor 624 is mirrored through transistor 626. In one example, the current mirror ratio between transistors 624 and 626 is 1:1 but can be other than 1:1 in other examples.

Current mirror 640 includes transistors 644, 646, and 648. In this example, transistors 664, 646, and 648 are NFETs but can be implemented as other types of transistors in other examples. The gates of transistors 644, 646, and 648 are coupled together and to the drain of transistor 644 and to terminal 641. The sources of transistors 644, 646, and 648 are coupled together and to terminal 154a or 154b of the respective OCP circuit 150a, 150b. The drain of transistor 646 is coupled to terminal 642, and the drain of transistor 648 is coupled to terminal 643. The drain current through transistor 644 is mirrored through transistors 646 and 648. In one example, the current mirror ratio between transistors 644 and 646 is 1:1 but can be other than 1:1 in other examples. Further, the current mirror ratio between transistors 644 and 648 is 1:n. The value of n may be, for example, 5.

Current mirror 660 includes transistors 664 and 666. In this example, transistors 664 and 666 are NFETs but can be implemented as other types of transistors in other examples. The gates of transistors 664 and 666 are coupled together and to the drain of transistor 664 and to terminal 661. The sources of transistors 664 and 666 are coupled together and to terminal 662. The drain of transistor 666 is coupled to terminal 663. The drain current through transistor 664 is mirrored through transistor 666. In one example, the current mirror ratio between transistors 684 and 686 is 1:m. The value of m may be, for example, 4.

Current mirror 680 includes transistors 684 and 686. In this example, transistors 684 and 686 are PFETs but can be implemented as other types of transistors in other examples. The gates of transistors 684 and 686 are coupled together and to the drain of transistor 684 and to terminal 681. The sources of transistors 684 and 686 are coupled together and to supply voltage terminal 609. The drain of transistor 686 is coupled to terminal 682. The drain current through transistor 684 is mirrored through transistor 686. In one example, the current mirror ratio between transistors 684 and 686 is 1:1 but can be other than 1:1 in other examples.

The current through transistors 624 and 616 and resistor 617 is current I1. The current through transistor 626 is current I2. Current source circuit 630 produces a current Ib that flows through transistor 644. The current through transistor 664 is current I3. The current through transistor 646 is current I4. The current through transistor 648 is current I4. The current through transistors 684 and 666 is current I5. The current through transistor 648 is current I6. The reference current Iref flows through transistor 686 and resistor 690. The voltage across resistor 690 resulting from reference current Iref flowing through resistor 690 is the threshold voltage OCP_TH.

The voltage divider formed by resistors 613 and 614 provides a voltage 605 that is proportional to voltage Vin to the positive input terminal of OP-AMP 615. The voltage 605 is:

$$Voltage 605 = Vin * \frac{{R}^{′}}{{R}^{′} + ( k - 1 ) * {R}^{′}} \qquad ( Eq . 1 )$$

Because the voltage on the negative input terminal of an operational amplifier is equal to the voltage on the positive input terminal of the operational amplifier, the voltage on the negative input terminal of the operational amplifier and accordingly across resistor 617 also is:

$$Voltage across resistor 617 = Vin * \frac{{R}^{′}}{{R}^{′} + ( k - 1 ) * {R}^{′}} \qquad ( Eq . 2 )$$

Current I1 is the voltage across resistor 617 divided by its resistance. In an example in which the resistance of resistor 617 is R′, current I1 is:

$$I 1 = \frac{VM}{k * {R}^{′}} \qquad ( Eq . 3 )$$

Accordingly, V2I converter 610 converts voltage Vin to current I1, and current I1 is proportional to voltage Vin.

The following description describes the operation of reference signal generation circuit 260 for current I2 larger than current Tb. Voltage Vin51 represents the voltage level of voltage Vin resulting in a current I1 that is larger than current Tb. Current mirror 620 mirrors current I1 as current I2. Because current I1 is proportional to voltage Vin, current I2 also is proportional to voltage Vin. In the example of FIG. 6 in which the current mirror ratio of current mirror 620 is 1:1, current I2 will be equal to current I1. Accordingly, current I2 will be larger than current Tb when current I1 is larger than current Ib. In an example in which the current mirror ratio between transistors 644 and 646 is 1:1, current I4 will be equal to current Ib. When current I2 is greater than current Tb, current I3 is the difference between currents I2 and I4, that is:

$$I 3 = I 2 - I 4 \qquad ( Eq . 4 )$$

Accordingly, when current I2 is greater than current Tb, current I3 is proportional to voltage Vin.

In the example of FIG. 6 in which the current mirror ratio of current mirror 660 is 1:m, current I5 is m*I3. Because current I3 is proportional to current voltage Vin, current I4 also is proportional to voltage Vin. For a current mirror ratio of 1:1 for current mirror 680, reference current Iref is equal to current I5, and accordingly, current Iref is proportional to current I5. Reference current Iref flows through resistor 690 and, accordingly, the reference voltage OCP_TH is proportional to voltage Vin as indicated by region 521 in FIG. 5. In region 421, the relationship between the reference voltage Vin and the reference current Iref is:

$$Iref = m ( \frac{Vin}{k * {R}^{′}} - Ib ) \qquad ( Eq . 5 )$$

The slope of reference current Iref in region 521 is m/(k*R′). Accordingly, the current mirror ratio, m, of current mirror 660 sets the slope of reference current Iref relative to voltage Vin.

For a voltage Vin equal to 0V, current I1 will be 0 amperes. If current I1 is 0 amperes, current I2 will be 0 amperes as well. If current I2 is 0 amperes, currents I3 and I4 will be 0 amperes as well. If current I3 is 0 amperes, current I5 will be 0 amperes, and accordingly, reference current Iref will be amperes. If reference current Iref is 0 amperes, reference voltage OCP_TH will be 0V. This condition, voltage Vin and reference voltage OCP_TH both at 0V, is identified in FIG. 5 by point 551.

For levels of voltage Vin above 0V but below Vin51, current I1 is greater than 0 amperes but smaller than current Ib. If current I1 is less than current Ib, currents I3, I4, and I5 and reference current Iref are all at 0 amperes, and reference voltage OCP_TH also is at 0V, as shown in region 523 in FIG. 5.

As described above, for a level of voltage Vin above Vin51, the reference current Iref increases linearly with respect to voltage Vin as shown in region 521. The sum of currents I3 and I5 will not be greater than current I6. Current I6 is equal to n*Ib. Current I6 represents the upper limit of the sum of currents I3 and I5. Level Vin52 for voltage Vin represents the voltage Vin at which currents I3 and I5 are equal to I6. At levels of voltage Vin greater than Vin52, current I5, and accordingly current Iref, will not increase above Imax due to the upper limit of the sum of I3 and I5 imposed by current I6 through transistor 648. Accordingly, reference current Iref is a constant level Imax for levels of voltage Vin above Vin52. Current Imax is:

$$Imax = n * Ib * ( \frac{m}{m + 1} ) \qquad ( Eq . 6 )$$

Because reference voltage OCP_TH is proportional to reference current Iref, reference voltage OCP_TH also is a constant for levels of voltage Vin above Vin52. In region 522, the reference voltage OCP_TH, which is the product of the reference current Iref and the resistance of resistor 690, is:

$$OCP\_TH = \frac{( n * Ib )}{R\_ 690} * ( \frac{m}{m + 1} ) \qquad ( Eq . 6 )$$

where R_690 is the resistance of resistor 690.

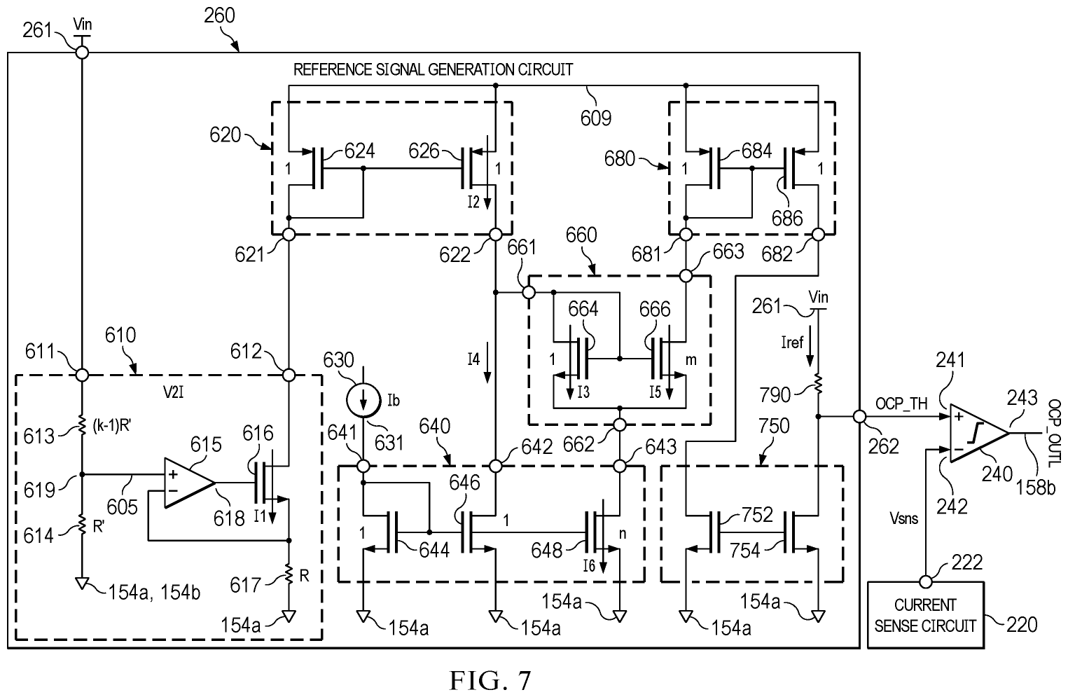

FIG. 7 is a schematic diagram of a reference signal generation circuit 260 for use in OCP protection circuit 150a for transistor 134 (FIG. 1). The reference signal generation circuit 260 in the example of FIG. 7 is generally the same as that of FIG. 6 but with the inclusion of an extra current mirror 750 coupled to terminal 682 of current mirror 680. Current mirror 750 includes transistors 752 and 754. A resistor 790 is coupled between terminal 261 and the source of transistor 754. The current through resistor 790 produces the reference voltage OCP_TH.

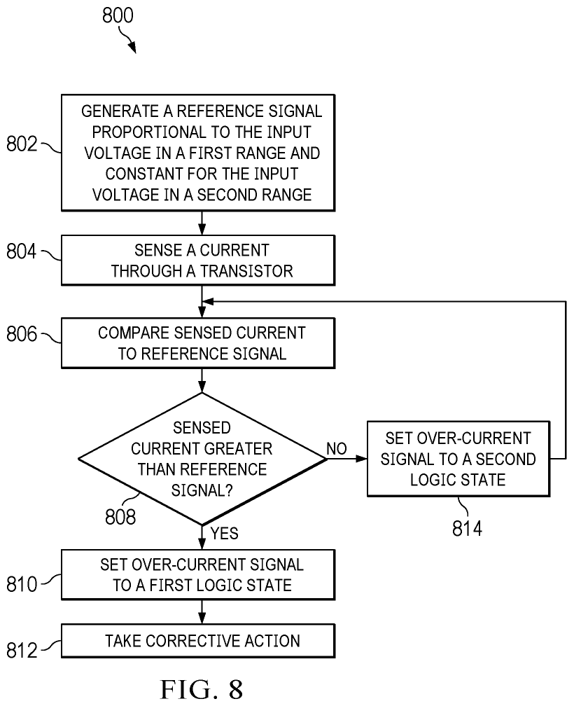

FIG. 8 is a flow diagram of a method 800 for detecting an overcurrent condition. The operations shown in the example of FIG. 8 may be performed by an OCP circuit as described above, e.g., OCP circuits 150a and/or 150b. Method 800 may include operations 802, 804, 806, 808, 810, 812, and 814. Operation 802 includes generating a reference signal proportional to the input voltage, e.g., Vin, within a first voltage and constant for the input voltage in a second voltage range. In one example, the first voltage range may be voltage range 521 in FIG. 5 and the second voltage range may be voltage range 522.

For operation 804, the method includes sensing a current through a transistor. The transistor may be either of the transistors of, for example, a half-bridge 130 usable as part of a motor driver, power converter, or other another application that includes a half-bridge. The current may be sensed as described above, e.g., as described with reference to the examples of FIGS. 2 and 3.

For operation 806, the sensed current is compared to the reference signal. In decision operation 808, the method determines whether the sensed current is greater than the reference signal. If the sensed current is greater than the reference signal (the “Y” branch), then at operation 810 the method includes setting an over-current signal to a first logic state (e.g., logic high). For example, the over-current signal may be output signal OCP_OUTH 158a from OCP circuit 150a or output signal OCP_OUTL 158b from OCP circuit 150b. In operation 812, in response to a first logic state of the over-current signal, a controller, e.g., controller 110, may take corrective action. For example, the controller may turn off the transistor whose current is determined to be too high or turn off the entire half-bridge including the transistor. If, however, the sensed current is not greater than the reference signal, then at operation 814, the over-current signal is set to a second logic state, e.g., logic low, indicating that no over-current condition has been detected, and control loops back to operation 806.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's terminals. In the context of a FET, the terminals are the gate, drain, and source. In the context of a BJT, the terminals are the base, collector, and emitter.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described examples, and other examples are possible, within the scope of the claims.

What is claimed is:

1. A reference signal generation circuit, comprising:
a voltage-to-current (V2I) converter having a terminal;
a first current mirror having a first terminal and a second terminal, the first terminal coupled to the terminal of the V2I converter;
a second current mirror having a first terminal, a second terminal, and a third terminal, the first terminal of the second current mirror coupled to the second terminal of the first current mirror; and
a third current mirror having a first terminal coupled to the second terminal of the first current mirror, and the third current mirror coupled to the third terminal of the second current mirror.

2. The reference signal generation circuit of claim 1, wherein the third current mirror has a second terminal, and the reference signal generation circuit further comprises a fourth current mirror having a first terminal coupled to the second terminal of the third current mirror.

3. The reference signal generation circuit of claim 2, wherein the third current mirror has a first field effect transistor (FET) and a second FET, the first FET has a source terminal, the second FET has a source terminal, and the source terminals of the first and second FETs are coupled together and to the third terminal of the second current mirror.

4. The reference signal generation circuit of claim 1, wherein
the second current mirror has a current mirror ratio of 1:n between the first terminal of the second current mirror and the third terminal of the second current mirror;
the third current mirror has a second terminal and a current mirror ratio of 1:m between the first terminal of the third current mirror and the second terminal of the third current mirror; and
wherein m is different than n.

5. The reference signal generation circuit of claim 1, further comprising a current source circuit having terminal coupled to the first terminal of the second current mirror.

6. The reference signal generation circuit of claim 1, wherein the third current mirror has a second terminal, and the reference signal generation circuit comprises a fourth current mirror having a terminal coupled to the second terminal of the third current mirror.

7. The reference signal generation circuit of claim 6, wherein the terminal of the fourth current mirror is a first terminal, the fourth current mirror has a second terminal, and the reference signal generation circuit includes a resistor coupled to the second terminal of the fourth current mirror.

8. An integrated circuit (IC), comprising:
a first transistor;
a current sense circuit having a first and second terminals, the first terminal coupled to the first transistor;
a comparator having first and second comparator terminal, the second comparator terminal coupled to the second terminal of the current sense circuit; and
a reference signal generation circuit including:
a voltage-to-current (V2I) converter having a terminal;
a first current mirror having a first terminal and a second terminal, the first terminal coupled to the terminal of the V2I converter;
a second current mirror having a first terminal, a second terminal, and a third terminal, the first terminal of the second current mirror coupled to the second terminal of the first current mirror; and
a third current mirror having a first terminal and a second terminal, the first terminal of the third current mirror coupled to the second terminal of the first current mirror, the third current mirror coupled to the third terminal of the second current mirror, and the second terminal of the third current mirror coupled to the first terminal of the comparator.

9. The IC of claim 8, wherein the third current mirror has a first field effect transistor (FET) and a second FET, the first FET has a source terminal, the second FET has a source terminal, and the source terminals of the first and second FETs are coupled together and to the third terminal of the second current mirror.

10. The IC of claim 8, wherein:
the second current mirror has a current mirror ratio of 1:n between the first terminal of the second current mirror and the third terminal of the second current mirror;
the third current mirror has a second terminal and a current mirror ratio of 1:m between the first terminal of the third current mirror and the second terminal of the third current mirror; and
wherein m is different than n.

11. The IC of claim 1, further comprising a current source circuit having a terminal coupled to the first terminal of the second current mirror.

12. An integrated circuit (IC), comprising:
a first transistor;
a current sense circuit having a first and second terminals, the first terminal coupled to the first transistor;
a reference signal generation circuit having first and second terminals, the reference signal generation circuit configured to generate a signal at the second terminal that, in a first voltage range, is a function of a voltage at the first terminal of the reference signal generation circuit; and
a comparator having a first terminal and a second terminal, the first terminal of the comparator coupled to the second terminal of the reference signal generation circuit, and the second terminal of the comparator coupled to the second terminal of the current sense circuit.

13. The IC of claim 12, wherein the reference signal generation circuit is configured to generate the signal at the second terminal that, in a second voltage range, is approximately constant.

14. The IC of claim 13, wherein the second voltage range is above the first voltage range.

15. The IC of claim 12, wherein the reference signal generation circuit comprises:
a first current mirror having first and second terminals;
a current source circuit having a terminal;
a second current mirror having first, second, and third terminals, the first terminal of the second current mirror coupled to the terminal of the current source circuit, and the second terminal of the second current mirror coupled to the second terminal of the first current mirror; and
a third current mirror having a first and second terminals, the first terminal of the third current mirror coupled to the second terminal of the first current mirror, and the second terminal of the third current mirror coupled to the third terminal of the second current mirror.

16. The IC of claim 15, further comprising a voltage-to-current (V2I) converter having first and second terminals, the first terminal of the V2I converter coupled to the first terminal of the reference signal generation circuit, and the second terminal of the V2I converter coupled to the first terminal of the first current mirror.

17. The IC of claim 15, wherein the third current mirror has a third terminal, and the driver further comprises a fourth current mirror having a first terminal coupled to the third terminal of the third current mirror.

18. The IC of claim 17, wherein the third current mirror has a first field effect transistor (FET) and a second FET, the first FET has a source terminal, the second FET has a source terminal, and the source terminals of the first and second FETs are coupled together and to the third terminal of the third current mirror.

19. The IC of claim 15, wherein
the second current mirror has a current mirror ratio of 1:n between the first and third terminals of the second current mirror;
the third current mirror has a third terminal and has a current mirror ratio of 1:m between the first and third terminals of the third current mirror; and
wherein m is different than n.

20. The IC of claim 12, wherein the first transistor has a control terminal, and the comparator has an output, and the IC includes a controller having a first terminal coupled to the control terminal, the controller also has a second terminal coupled to the output of the comparator.
